(19) United States
(12) Patent Application Publication
(10) Pub. No.: US 2024/0410944 A1
(43) Pub. Date: Dec. 12, 2024

(54) METHOD AND ARRANGEMENT FOR TESTING THE FUNCTIONALITY OF A SEMICONDUCTOR SWITCH

(71) Applicant: HELLA GmbH & Co. KGaA, Lippstadt (DE)

(72) Inventors: Stephan BISANZ, Bochum (DE); Jan Frederik BUTHKE, Lippstadt (DE); Niklas MAY-JOHANN, Lippstadt (DE); Lennart WINTERBERG, Lippstadt (DE)

(73) Assignee: HELLA GmbH & Co. KGaA, Lippstadt (DE)

(21) Appl. No.: 18/812,705

(22) Filed: Aug. 22, 2024

Related U.S. Application Data
(63) Continuation of application No. PCT/EP2023/052792, filed on Feb. 6, 2023.

(30) Foreign Application Priority Data
Feb. 22, 2022 (DE) 10 2022 104 088.7

(51) Int. Cl. G01R 31/327; G01R 31/00

(52) U.S. Cl. CPC G01R 31/327; G01R 31/006

(57) ABSTRACT

An arrangement for testing the functionality of a semiconductor switch that is used as a fuse in a power supply line of a load in a motor vehicle electrical system. A voltage on the load side of the semiconductor switch or the current through the semiconductor switch can be detected. A controller is connected to the output and a monitoring component is connected to an input. The controller is configured to generate a signal which is applied to the output and via which the semiconductor switch can be switched off for a defined time interval in order to test the functionality, the time interval being so short that the functionality of the load is not impaired by this switching off. The monitoring component is configured to monitor the current applied to the input during the time interval or the voltage applied to the input during the time interval.

This nonprovisional application is a continuation of International Application No. PCT/EP2023/052792, which was filed on Feb. 6, 2023, and which claims priority to German Patent Application No. 10 2022 104 088.7, which was filed in Germany on Feb. 22, 2022, and which are both herein incorporated by reference.

### BACKGROUND OF THE INVENTION

### Field of the Invention

The invention relates to a method and an arrangement for testing the functionality of a semiconductor switch that is used as a fuse in a power supply line of a load in a motor vehicle electrical system.

### Description of the Background Art

It is generally customary and often also mandatory to provide fuses in electrical devices in order to protect the device or parts of the device from high currents. In motor vehicle electrical systems and also other devices, inexpensive fusible cutouts are usually used, which melt in the event of an excessively high current load and thereby interrupt the current path through the fuse. New fuses must then be installed to close the current path. Instead of fusible cutouts, sometimes semiconductor switches are also installed as electronic fuses, which disconnect loads that are connected to the supply through the semiconductor switch from the supply in the event of high currents in place of a fusible cutout. The advantage of using semiconductor switches as fuses resides in the fact that the semiconductor switches can be closed again when the high current or the malfunction that has caused the high current is remedied. This can also take place automatically. Furthermore, the semiconductor switches can also be driven to open when a malfunction of the device is present that does not cause an excessively high current through the semiconductor switch, but instead has other consequences that, for example, could lead to permanent damage to the device.

In contrast to a fusible cutout, which is robust and, on account of its characteristics, reliably interrupts the current path in the event of a high current, it is possible with a semiconductor switch that, on account of a fault, the semiconductor switch does not open in the case when it should interrupt the current, whether it be because the semiconductor switch is faulty or because a control signal that is intended to cause the semiconductor switch to open is not generated or does not arrive at the control signal input of the semiconductor switch.

It is therefore extremely important to detect such faults in order to subsequently be able to remedy them.

### SUMMARY OF THE INVENTION

It is therefore an object of the invention to provide an arrangement that has an output that is connected to a control terminal of the semiconductor switch, and has an input by means of which the voltage on the load side of the semiconductor switch or the current through the semiconductor switch can be sensed. The arrangement also has a controller that is connected to the output, and has a monitoring component that is connected to the input. The controller can be configured to generate a signal that is applied to the output, via which the semiconductor switch can be switched off for testing the functionality, wherein, as a result of the switch-off, the voltage at the output of the semiconductor switch falls below a threshold value for a defined time interval, and wherein the time interval is so short that the functionality of the load continues to be provided or is not impaired by this switch-off, and the monitoring component can be configured to monitor the current applied to the input during the time interval or the voltage applied to the input during the time interval.

With this arrangement according to the invention, in particular, a method according to the invention for testing the functionality of the semiconductor switch that is used as a fuse can be carried out in which the semiconductor switch is switched off for testing the functionality, wherein the time interval in which the voltage at the output of the semiconductor switch falls below a threshold value as a result of the switch-off is so short that the functionality of the load continues to be provided or is not impaired by this switch-off, and that a current through the semiconductor switch or a voltage at the semiconductor switch is monitored during the time interval.

Short-duration interruptions of the power supply, current fluctuations, or voltage fluctuations in supply networks usually have no effect on the ability of the loads connected to the networks to function, since the loads often have been designed such that they are robust to such occurrences. Frequently, for specific types of supply networks, it is also specified in standards or other regulations that such occurrences are permitted to arise within fixed limits in the networks without resulting in a failure of the loads. The loads must therefore even be designed such that they withstand current interruptions, current fluctuations, or voltage fluctuations without failing. The present invention makes use of this robustness of the loads in order to test the functionality of the semiconductor switches used as fuses. The length of the time interval for which the semiconductor switch is switched off, which is to say opened, is therefore specified such that the time interval is shorter than the length of an interruption or fluctuation of the current or the voltage that is tolerated in the supply network. Thus, in a method for testing of, in particular, a semiconductor switch used in a motor vehicle electrical system, provision can be made that the voltage at the output of the semiconductor drops below a threshold value for a time period that is not longer than 100 μs.

The semiconductor switch can be switched off several times in a row for a series of switch-offs for testing the functionality of the semiconductor switch, wherein the switch-off time is lengthened from switch-off to switch-off until the time interval for which the voltage at the output of the semiconductor switch is below the threshold value has reached a maximum of 100 μs. The series can be terminated early, before reaching a length of the time interval of 100 μs, if the monitoring shows that the semiconductor switch interrupts the current path passing through it during the last switch-off. In this way, the ability of the semiconductor switch to function can be tested without going to the limit of the permissible interruption when doing so. The interruption can therefore reduce an effect on loads that may not be quite so robust.

The testing according to the invention of the semiconductor switch can be carried out at times when the operation of a safety-critical load is not required. For a motor vehicle electrical system, for example, this can be when the vehicle is stopped, for example after the vehicle is started, after the power train of the vehicle is switched off, or while the vehicle is stopped at a red light, for example.

The current passing through the semiconductor switch or the voltage present on the load side of the semiconductor switch can be sampled with a period that is very small in comparison to the length of the switch-off time during which the semiconductor switch is switched off for testing. The period of the sampling can be a fraction of the length of the maximum permissible time interval, for example. In this way, it is possible to ensure that rapid changes in the current or the voltage are sensed that can be sufficient to indicate the ability of the semiconductor switch to function.

In a motor vehicle electrical system, it is possible to provide a semiconductor switch used as a fuse, an arrangement according to the invention for testing the semiconductor switch, and a load that is connected to the power supply of the motor vehicle electrical system through the semiconductor switch. In such a case, the load can have a power supply input through which the load is connected to the motor vehicle electrical system, wherein the load has a reverse polarity protection diode that is connected to a first terminal of the power supply input, and wherein the load has a capacitor that is connected on the one hand to a terminal of the reverse polarity protection diode facing away from the first terminal of the supply input and is connected on the other hand to a second terminal of the supply input. Such a capacitor has the advantage that the supply voltage within the load is not interrupted or fluctuates less than the supply voltage applied to the power supply input, despite an interruption or a fluctuation of the voltage at the power supply input of the load. In such a case, the reverse polarity protection diode prevents the said capacitor from discharging through the electrical system at the power supply input. This achieves the result that the energy stored in the capacitor can be used to supply the load.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows in a schematic representation, a block diagram of a motor vehicle electrical system with an arrangement according to the invention, and

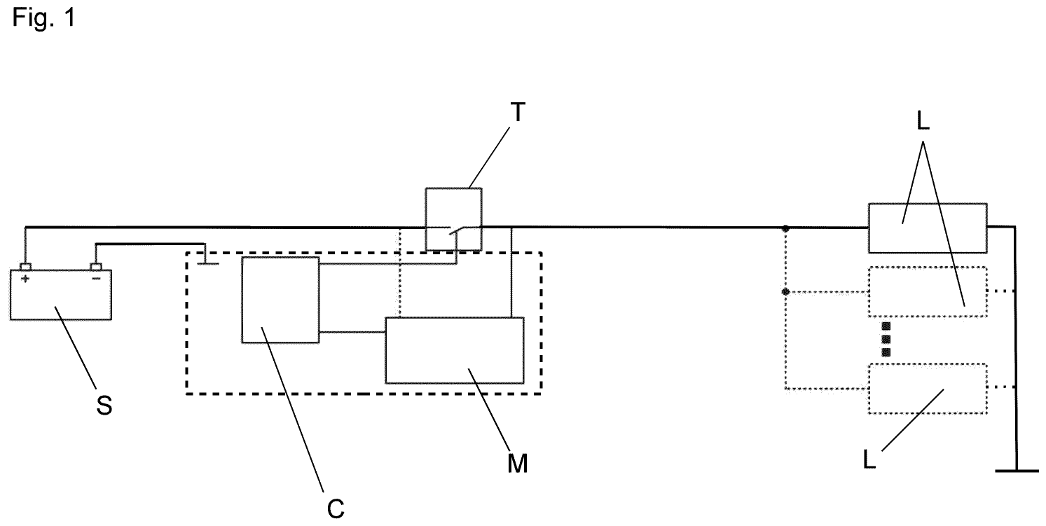

FIG. 2 shows in a schematic representation, an input of a load of the motor vehicle electrical system from FIG. 1.

### DETAILED DESCRIPTION

The motor vehicle electrical system has a battery as source S for electrical energy. This battery S is connected to a multiplicity of loads L that are supplied with electrical energy from the battery. Instead of or in addition to the battery S, other sources of electrical energy could also be provided in the electrical system, in particular generators. The battery defines a nominal voltage of the electrical system.

Provided in the connection between a battery pole for a positive potential in the electrical system and the loads is a semiconductor switch T that is arranged in the current path between the battery pole for the positive potential and a terminal for the positive potential of a power supply input of the load L. With this switch, the current path can be interrupted and established.

The arrangement according to the invention has a monitoring component M, with which the voltage with respect to ground can be sensed on the load side of the semiconductor switch T. The monitoring component can be, for example, a sensor, voltage detector that is an IC, or any device known to one skilled in the art. Alternatively, the voltage across the switch could also be sensed. If the semiconductor switch T is closed, the nominal voltage should appear at the load-side terminal of the semiconductor switch when the voltage is measured between the load side of the semiconductor switch and ground. If, in contrast, the voltage across the semiconductor switch is measured, a voltage much smaller than the nominal voltage would have to be present, which in the best case is even 0 V. On the other hand, if the semiconductor switch T is open, the voltage at the load-side terminal of the semiconductor switch T drops, possibly even to 0 V. Whether the voltage drops to 0 V depends on factors including whether any energy storage devices, in particular capacitors, are provided on the load side of the semiconductor switch, which devices must first discharge before the voltage drops to 0 V. The voltage across the open semiconductor switch T, in contrast, will rise. The voltage either rises abruptly or more slowly until it has reached the nominal voltage, depending on whether discharges of storage devices, in particular of capacitors, on the load side take place or not.

With the monitoring component M, it is thus possible to detect whether the semiconductor switch T is open or closed. This detection can be passed on by the monitoring component, which has an output for this purpose.

The arrangement according to the invention additionally has a controller C for generating a signal that is applied to the output of the arrangement, via which the semiconductor switch T can be switched off for a switch-off time to test the functionality, wherein the switch-off is so short that the functionality of the load L is not impaired by this switch-off. The loads therefore do not change their behavior on account of the short-duration opening of the semiconductor switch T, and retain their functionality. The brief opening of the semiconductor switch T does, however, have the result that the voltage across the switch increases for a short time or the voltage between the load-side terminal of the semiconductor switch T and ground is reduced for a short time. This can then be identified by the monitoring component M, which is connected through its output to an input of the controller and reports the change in voltage to the controller.

The controller can then test whether the driving of the semiconductor switch results in a voltage change. If this is the case, the semiconductor switch is functional and capable of interrupting the electric circuit passing through the semiconductor switch T when driven appropriately, for example when an excessively large current in the electrical system should be prevented by this means.

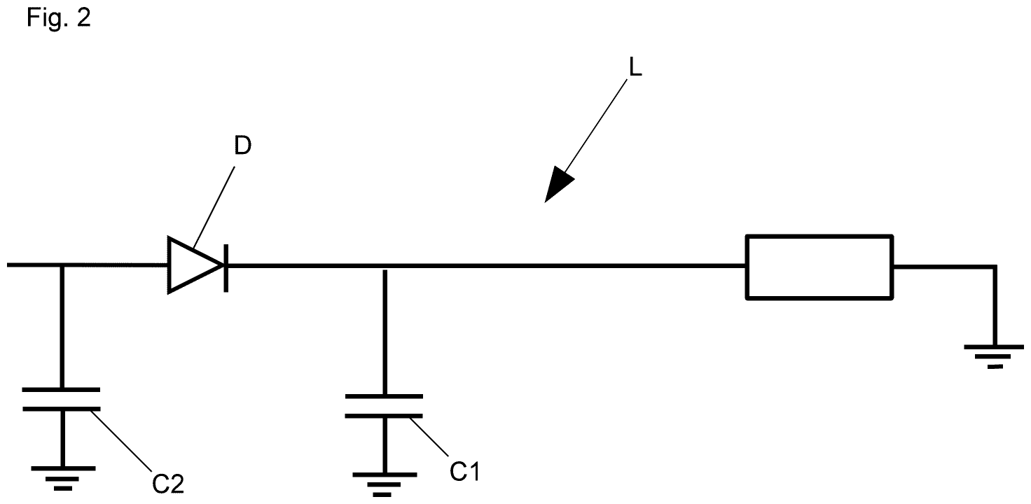

A capacitor C2 is arranged in the input region of the load L shown in FIG. 2, parallel to the two terminals. The terminal for the positive potential of the supply voltage is also connected to an anode of a reverse polarity protection diode. Its cathode is connected on the one hand to a circuit of the load and on the other hand to another capacitor C1, whose second terminal is connected to the terminal of the load for the ground potential of the input of the load. The capacitor C1 has a capacitance that is greater than the capacitance of the capacitor C2. If the semiconductor switch is now switched off, the capacitor discharges through a voltage divider that is used to measure the voltage at the load-side terminal of the semiconductor switch T. In this case, the voltage quickly diminishes on account of the small capacitance of the capacitor C2. The capacitor C1, in contrast, discharges through the circuit of the load L and supplies the same with a comparatively stable voltage during the interruption caused by the opening of the semiconductor switch T. The brief opening of the semiconductor switch for testing the functionality of the semiconductor switch therefore has hardly any effect on the circuit of the load.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An arrangement for testing a functionality of a semiconductor switch that is used as a fuse in a power supply line of a load in a motor vehicle electrical system, the arrangement comprising:
an output that is connected to a control terminal of the semiconductor switch;
an input via which the voltage on the load side of the semiconductor switch or the current through the semiconductor switch is sensed; and
a controller that is connected to the output, and has a monitoring component that is connected to the input,
wherein the controller is configured to generate a signal that is applied to the output, via which the semiconductor switch is switched off for testing the functionality,
wherein, as a result of the switch-off, the voltage at the output of the semiconductor switch falls below a threshold value for a defined time interval, and the time interval being so short that the functionality of the load continues to be provided through this switch-off, and
wherein the monitoring component is configured to monitor the current applied to the input during the time interval or the voltage applied to the input during the time interval.

2. A method for testing a functionality of a semiconductor switch according to claim 1, the method comprising:
providing the semiconductor switch as a fuse in a power supply line of a load in a motor vehicle electrical system; and
switching the semiconductor switch off for testing the functionality, wherein the voltage at the output of the semiconductor switch falls below a threshold value for a defined time interval as a result of the switch-off, and wherein the time interval is so short that the functionality of the load continues to be provided through this switch-off; and
monitoring a current through the semiconductor switch or a voltage at the semiconductor switch during the time interval.

3. The method according to claim 2, wherein the time interval in which the voltage at the output of the semiconductor switch is below the threshold value is at most 100 μs long.

4. The method according to claim 2, wherein the semiconductor switch is switched off for a series of switch-offs in a row for testing the functionality of the semiconductor switch, and wherein the time interval in which the voltage at the output of the semiconductor switch is below the threshold value is permitted to be a maximum of 100 μs.

5. The method according to claim 4, wherein the series is terminated before the time interval in which the voltage at the output of the semiconductor switch is below the threshold value has reached 100 μs if the monitoring shows that the semiconductor switch interrupts the current path passing through it during the last time interval.

6. The method according to claim 2, wherein the current passing through the semiconductor switch or the voltage present on the load side of the semiconductor switch is sampled with a period that is a fraction of the length of the time interval during which the semiconductor switch is switched off for testing.

7. An arrangement in a motor vehicle electrical system comprising the arrangement according to claim 1 and a load, wherein the load has a power supply input through which the load is connected to the motor vehicle electrical system, wherein the load has a reverse polarity protection diode that is connected to a first terminal of the power supply input, and wherein the load has a capacitor that is connected to a terminal of the reverse polarity protection diode facing away from the first terminal of the supply input and is connected to a second terminal of the supply input.
